(19) United States
(12) Patent Application Publication
(10) Pub. No.: US 2015/0287881 A1
(43) Pub. Date: Oct. 8, 2015

(54) Light Emitting Diode Device

(71) Applicant: National Chiao Tung University, Hsinchu City (TW)

(72) Inventors: Hung-Shen CHU, Hsinchu County (TW); Da-Wei LIN, New Taipei City (TW); Hao-Chung KUO, Hsinchu City (TW)

(21) Appl. No.: 14/325,906

(22) Filed: Jul. 8, 2014

(30) Foreign Application Priority Data
Apr. 2, 2014 (TW) 103112245

(51) Int. Cl. H01L 33/22; H01L 33/00; H01L 33/42; H01L 33/32; H01L 33/06; H01L 33/12

(52) U.S. Cl. CPC H01L 33/22; H01L 33/06; H01L 33/12; H01L 33/42; H01L 33/32; H01L 33/007

(57) ABSTRACT

A light emitting diode device comprises the transparent conductive layer is formed on the conductive substrate, the p-type semiconductor layer is formed on the transparent conductive layer, the active layer is formed on the p-type semiconductor layer, and the n-type semiconductor layer is formed on the active layer, the buffer layer is formed on the n-type semiconductor layer, and a metal electrode is formed on a rough and uneven surface of the buffer layer, in which the electrical property of the n-type semiconductor layer is opposites to that of the p-type semiconductor layer. The reflective effect within the light emitting diode device can be increased. In addition, by reducing the thickness of the undoped GaN layer, the absorption of ultraviolet light inside the components of the light emitting diode device can be reduced.

### BACKGROUND OF THE INVENTION

1. Field of the Invention

The present invention relates to a light emitting diode device, particularly to a light emitting diode device able to reduce the absorption of ultraviolet light and increase the light extraction efficiency.

2. Description of the Prior Art

The application of light emitting diode (LED) is much more popularized in various electronic products and industry day by day. Due to the required energy cost of the light emitting diode is far below the conventional incandescent lamp or fluorescent lamp, and the size of single light emitting diode is much compact than the conventional illuminator, so that the demand of the light emitting diode is also increased day by day under the trend of light, thin, short and small electronic product.

The light emitting diode is the light emitting device which is able to convert the electric energy into the light energy directly. Because it is not necessary to convert the electric energy by using the mechanism of the heat-induced emission, the light emitting diode is also called the cold light emitting device. Except there is high light emitting efficiency, the light emitting diode is also a small solid state illuminator, which can be used to make the semiconductor chip with p-n junction structure. After the voltage is applied to both ends of this p-n junction, the electrons and holes will flow towards this p-n junction immediately, and bond together to release the photons.

As for the luminance of the light emitting diode, it is generally acknowledged that the efficiency of current light emitting diode is about a half of that of cold cathode fluorescent lamp, even its light emitting effect is about the same as that of cold cathode fluorescent lamp. The light emitting efficiency of the light emitting diode mainly relates to two factors: the first one is the light emitting efficiency of the semiconductor, and the second one is the light release rate of encapsulated semiconductor chip. The main development direction for the light emitting efficiency of the semiconductor chip comprises: the research and development of the electroluminescence material, and the research on enhancing the crystallinity of the semiconductor chip, in order to increase the quantum effect inside the semiconductor chip.

### SUMMARY OF THE INVENTION

According to the shortcoming of the prior art, the main purpose of the present invention is to disclose a light emitting diode device. The patterned sapphire substrate or the nano-patterned sapphire substrate in the light emitting diode device is favorable to the growth of gallium nitride, and can reduce the defect and raise the internal quantum effect (IQE) to increase the epitaxy quality.

Another purpose of the present invention is to disclose a light emitting diode device. The transparent conductive layer in the light emitting diode can increase the current spreading efficiency and reduce the forward voltage, in order to raise the light emitting efficiency of the light emitting diode device.

The other purpose of the present invention is to disclose a light emitting diode device. It can reduce the thickness of the undoped GaN layer, reduce the absorption of ultraviolet light inside the components of the light emitting diode device, and increase the external light extraction efficiency, in order to raise the light emitting efficiency of the light emitting diode device.

According to the abovementioned purposes, the present invention discloses a light emitting diode device, which comprises a conductive substrate, the transparent conductive layer is formed on the conductive substrate, the p-type semiconductor layer is formed on the transparent conductive layer, the active layer is formed on the p-type semiconductor layer, and the n-type semiconductor layer is formed on the active layer, the buffer layer is formed on the n-type semiconductor layer, and a metal electrode is formed on a rough and uneven surface of the buffer layer, in which the electrical property of the n-type semiconductor layer is opposites to that of the p-type semiconductor layer. The reflective effect within the light emitting diode device can be increased. In addition, by reducing the thickness of the undoped GaN layer, the absorption of ultraviolet light inside the components of the light emitting diode device can be reduced, the external light extraction efficiency can be increased and the light emitting efficiency of the light emitting diode device can be raised.

The present invention discloses a manufacturing method of the light emitting diode device, comprising: providing a substrate, there is a rough and uneven surface on the substrate, the buffer layer is formed on the substrate, the n-type semiconductor layer is formed on the buffer layer, the active layer is formed on the n-type semiconductor layer, the p-type semiconductor layer is formed on the active layer, the transparent conductive layer is formed on the p-type semiconductor layer, the conductive substrate is bonded with the transparent conductive layer to carry on the lift-off procedure. According to the rough and uneven surface on the substrate, the substrate is separated from the buffer layer mutually, so that a plurality of rough and uneven surface is formed on the buffer layer. A roughing procedure is applied to the rough and uneven surface of the buffer layer, so that the rough and uneven surface of the buffer layer has a coarse surface, and a metal electrode is formed on the buffer layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates the cross-sectional view of the light emitting diode device according to the technology disclosed by the present invention.

FIG. 2 illustrates the cross-sectional view of lifting off the substrate and the buffer layer, as well as forming a rough and uneven surface on the buffer layer according to the technology disclosed by the present invention.

FIG. 3 illustrates forming a metal electrode on the buffer layer according to the art disclosed by the present invention.

### DESCRIPTION OF THE PREFERRED EMBODIMENT

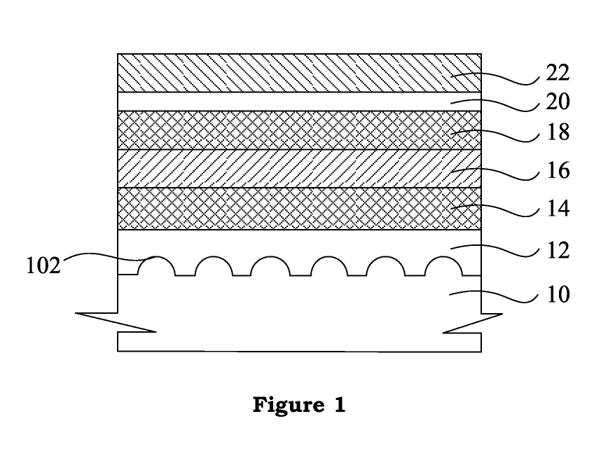

First, please refer to FIG. 1. FIG. 1 illustrates the cross-sectional view of the light emitting diode device according to the technology disclosed by the present invention. As shown in FIG. 1, the structure includes a substrate 10, a buffer layer 12, a n-type semiconductor layer 14, an active layer 16, a p-type semiconductor layer 18, a transparent conductive layer 20 and a conductive substrate 22 from bottom to top.

In an embodiment of the present invention, the substrate 10 is the patterned sapphire substrate or the nano-patterned sapphire substrate. Its purpose is to raise the growth of gallium nitride (GaN) layer on the substrate 10, increase the epitaxy quality, reduce the defect of GaN layer, and increase the internal quantum effect (IQE). After the substrate 10 is patterned, the surface becomes a rough and uneven surface 102. The buffer layer 12 is formed on the substrate 10. The buffer layer 12 is formed on the substrate 10 by the epitaxy growing method, and the buffer layer 12 is the undoped GaN layer. In the present invention, the undoped GaN layer 12 is used as the buffer layer. It is because the undoped GaN layer 12 has good compatibility with respect to the patterned sapphire substrate or the nano-patterned sapphire substrate, so that the light emitting diode device has better epitaxy quality.

Then, please refer to FIG. 1 again. The n-type semiconductor layer 14, the active layer 16 and the p-type semiconductor layer 18 are formed on the buffer layer 12 by the same epitaxy growing method. The material of the n-type semiconductor layer 14 and the p-type semiconductor layer 18 is GaN, in which the electrical property of the n-type semiconductor layer is opposites to that of the p-type semiconductor layer. In addition, the active layer 16 is the multi-quantum well.

Then, please refer to FIG. 1 continuously. The transparent conductive layer 20 is formed on the p-type semiconductor layer 18. The material of the transparent conductive layer 20 may be the grapheme, zinc oxide (ZnO) or indium tin oxide (ITO), wherein the better one is ITO. In the present invention, the transparent conductive layer 20 can increase the current spreading efficiency, and reduce the forward voltage, so that the current of the light emitting diode device will not change rapidly, so as to prevent the problem of device collapse due to sudden drop or sudden rise of current in the light emitting diode device. And then, the conductive substrate 22 is formed on the transparent conductive layer 20 by the bonding method, which is used as the electrode of the light emitting diode device, the material may be the titanium (Ti), aluminum (Al), tin (Sn), nickel (Ni), gold (Au), copper (Cu), chromium (Cr), silver (Ag), platinum (Pt), tungsten (W) or their alloy (selected from the group).

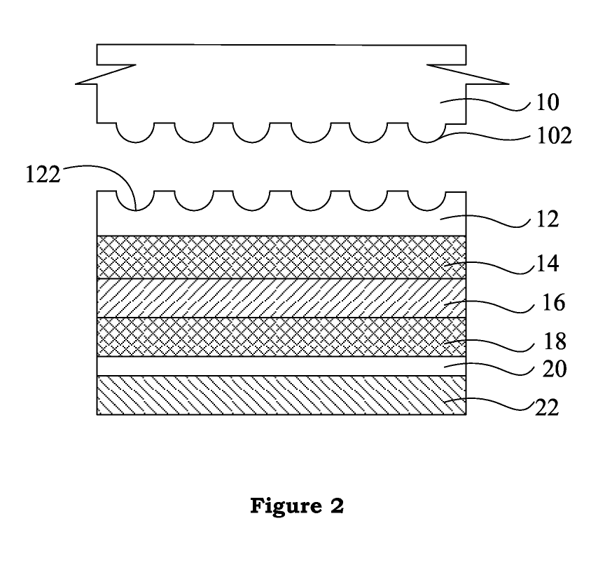

Then, please refer to FIG. 2. FIG. 2 illustrates the cross-sectional view of lifting off the substrate and the buffer layer, as well as forming a rough and uneven surface on the buffer layer according to the technology disclosed by the present invention. In FIG. 2, the upside down diagram of FIG. 1 is illustrated. According to the lift-off technique used to form the pattern on the substrate previously, separate the substrate 10 and the buffer layer 12. The lift-off technique may be laser lift-off technique or other dry or wet etching lift-off technique. After the substrate 10 and the buffer layer 12 are separated, the rough and uneven surface 122 will be formed on the surface of buffer layer due to the original pattern on the substrate 10.

And then, carry on the roughing procedure for the rough and uneven surface 122 on the buffer layer 12, so that the surface of buffer layer 12 not only has the rough and uneven surface as shown be index 122 in FIG. 2, but also has the coarse surface as shown be index 124. The purpose is to increase the reflective effect within the light emitting diode device. Therefore, when the light is emitting from the light emitting diode device, will have better light extraction efficiency and obtain better light emitting efficiency. In an embodiment of the present invention, the etching technique, particularly the dry etching technique is used for the roughing procedure.

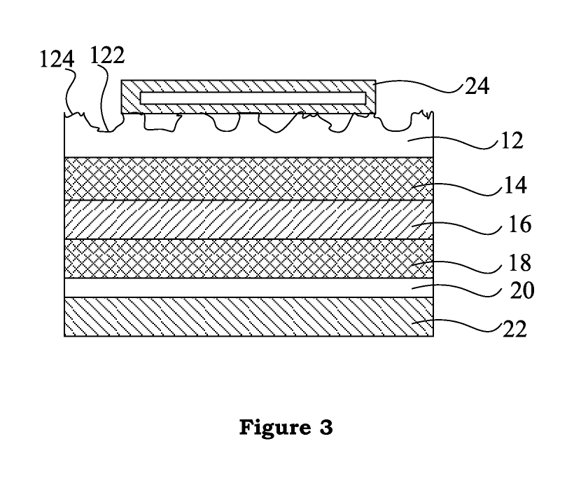

Then, please refer to FIG. 3. FIG. 3 illustrates forming a metal electrode on the buffer layer according to the technology disclosed by the present invention. In FIG. 3, the metal electrode 24 is formed on the rough and uneven surface 122 and the coarse surface 124 of the buffer layer 12. In this embodiment, the metal electrode 24 is used as the electrode of the light emitting diode device, the material may be the titanium (Ti), aluminum (Al), tin (Sn), nickel (Ni), gold (Au), copper (Cu), chromium (Cr), silver (Ag), platinum (Pt), tungsten (W) or their alloy (selected from the group).

According to the light emitting diode device disclosed by the present invention, the laser lift-off technique can be used to reduce the thickness of the undoped GaN layer on the buffer layer 12, reduce the absorption of ultraviolet light inside the components of the light emitting diode device, and increase the external light extraction efficiency through the rough and uneven surface 122 and the coarse surface 124 of the buffer layer 12, in order to raise the light emitting efficiency of the light emitting diode device.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A light emitting diode device, comprising:
a conductive substrate;
a transparent conductive layer, said transparent conductive layer is formed on said conductive substrate;
a p-type semiconductor layer, said p-type semiconductor layer is formed on said transparent conductive layer;
an active layer, said active layer is formed on said p-type semiconductor layer;
an n-type semiconductor layer, said n-type semiconductor layer is formed on said active layer, an electrical property of said n-type semiconductor layer is opposite to said electrical property of said p-type semiconductor layer;
a buffer layer, said buffer layer is formed on said n-type semiconductor layer, and said buffer layer has a rough and uneven surface; and
a metal electrode, said metal electrode is formed on said rough and uneven surface of said buffer layer.

2. The device according to claim 1, wherein the transparent conductive layer is selected from the group consisting of grapheme, indium tin oxide (ITO) and zinc oxide (ZnO).

3. The device according to claim 1, wherein the buffer layer comprises an undoped GaN layer.

4. A manufacturing method of the light emitting diode device, comprising:
providing a substrate, wherein said substrate having a rough and uneven surface;
forming a buffer layer on said substrate;
forming an n-type semiconductor layer on said buffer layer;
forming an active layer on said n-type semiconductor layer;
forming a p-type semiconductor layer on said active layer;
forming a transparent conductive layer on said p-type semiconductor layer;
binding a conductive substrate on said transparent conductive layer;
carrying on a lift-off procedure according to said rough and uneven surface on said substrate, said substrate is separated from said buffer layer mutually, so that a rough and uneven surface is formed on said buffer layer;
a roughing procedure is applied to said rough and uneven surface of said buffer layer, so that said rough and uneven surface of said buffer layer has a coarse surface; and
a metal electrode is formed on said buffer layer.

5. The method according to claim 4, wherein the substrate is selected from the group consisting of the patterned sapphire substrate and the nano-patterned sapphire substrate.

6. The method according to claim 4, wherein the lift-off technique comprises laser lift-off technique.

7. The method according to claim 4, wherein the roughing procedure comprises the dry etching.
